(19) United States
(12) Patent Application Publication
(10) Pub. No.: US 2025/0366148 A1
(43) Pub. Date: Nov. 27, 2025

(54) DIFFUSION BARRIER LAYERS IN SEMICONDUCTOR DEVICES

(71) Applicant: Taiwan Semiconductor Manufacturing Company, Ltd., Hsinchu (TW)

(72) Inventors: Chia-Hsi WANG, Changhua (TW); Yen-Yu CHEN, Taichung (TW)

(73) Assignee: Taiwan Semiconductor Manufacturing Company, Ltd., Hsinchu (TW)

(21) Appl. No.: 19/292,755

(22) Filed: Aug. 6, 2025

Related U.S. Application Data
(63) Continuation of application No. 18/590,175, filed on Feb. 28, 2024.
(60) Provisional application No. 63/541,339, filed on Sep. 29, 2023.

(51) Int. Cl. H10D 64/68; H10D 30/62; H10D 64/01; H10D 64/23; H10D 64/27

(52) U.S. Cl. CPC H10D 64/685; H10D 30/6211; H10D 64/01; H10D 64/017; H10D 64/258; H10D 64/514

(57) ABSTRACT

A semiconductor device and a method of fabricating the semiconductor device are disclosed. The semiconductor device includes a substrate, a fin structure disposed on the substrate, and a gate structure. The gate structure includes a high-k gate oxide layer disposed on the fin structure, a diffusion barrier layer disposed on the high-k gate oxide layer, and a metal layer disposed on the diffusion barrier layer. The semiconductor device further includes a gate spacer disposed on the diffusion barrier layer and a source/drain (S/D) region disposed on the fin structure. A sidewall of the S/D region is in contact with a sidewall of the high-k gate oxide layer.

### CROSS-REFERENCE TO RELATED APPLICATIONS

This application is a continuation of U.S. patent application Ser. No. 18/590,175, titled “Diffusion Barrier Layers in Semiconductor Devices,” filed Feb. 28, 2024, which claims the benefit of U.S. Provisional Patent Application No. 63/541,339, titled “Semiconductor Device Structure and Method,” filed Sep. 29, 2023, each of which is incorporated by reference herein in its entirety.

### BACKGROUND

With advances in semiconductor technology, there has been increasing demand for higher storage capacity, faster processing systems, higher performance, and lower costs. To meet these demands, the semiconductor industry continues to scale down the dimensions of semiconductor devices, such as metal oxide semiconductor field effect transistors (MOSFETs), including planar MOSFETs, fin field effect transistors (diffusion barrier layer FinFETs), and gate-all-around field effect transistors (GAA FETs). Such scaling down has increased the complexity of semiconductor manufacturing processes.

### BRIEF DESCRIPTION OF THE DRAWINGS

Aspects of this disclosure are best understood from the following detailed description when read with the accompanying figures.

FIG. 1A illustrates an isometric view of a semiconductor device with diffusion barrier layers, in accordance with some embodiments.

FIGS. 1B-1D illustrate different cross-sectional views of a semiconductor device with diffusion barrier layers, in accordance with some embodiments.

FIGS. 2A and 2B illustrate different cross-sectional views of another semiconductor device with diffusion barrier layers, in accordance with some embodiments.

FIG. 3 is a flow diagram of a method for fabricating a semiconductor device with diffusion barrier layers, in accordance with some embodiments.

FIGS. 4-16 illustrate isometric and cross-sectional views of a semiconductor device with diffusion barrier layers at various stages of its fabrication process, in accordance with some embodiments.

FIG. 17 is a flow diagram of a method for fabricating a semiconductor device with diffusion barrier layers, in accordance with some embodiments.

FIGS. 18-22 illustrate cross-sectional views of another semiconductor device with diffusion barrier layers at various stages of its fabrication process, in accordance with some embodiments.

Illustrative embodiments will now be described with reference to the accompanying drawings. In the drawings, like reference numerals generally indicate identical, functionally similar, and/or structurally similar elements.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the process for forming a first feature over a second feature in the description that follows may include embodiments in which the first and second features are formed in direct contact, and may also include embodiments in which additional features may be formed between the first and second features, such that the first and second features may not be in direct contact. As used herein, the formation of a first feature on a second feature means the first feature is formed in direct contact with the second feature. In addition, the present disclosure may repeat reference numerals and/or letters in the various examples. This repetition does not in itself dictate a relationship between the various embodiments and/or configurations discussed.

Spatially relative terms, such as “beneath,” “below,” “lower,” “above,” “upper,” and the like may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

It is noted that references in the specification to “one embodiment,” “an embodiment,” “an example embodiment,” “exemplary,” etc., indicate that the embodiment described may include a particular feature, structure, or characteristic, but every embodiment may not necessarily include the particular feature, structure, or characteristic. Moreover, such phrases do not necessarily refer to the same embodiment. Further, when a particular feature, structure or characteristic is described in connection with an embodiment, it would be within the knowledge of one skilled in the art to effect such feature, structure or characteristic in connection with other embodiments whether or not explicitly described.

It is to be understood that the phraseology or terminology herein is for the purpose of description and not of limitation, such that the terminology or phraseology of the present specification is to be interpreted by those skilled in relevant art(s) in light of the teachings herein.

In some embodiments, the terms “about” and “substantially” can indicate a value of a given quantity that varies within 5-20% of the value (e.g., ±1%, ±2%, ±3%, ±4%, ±5%, ±10%, ±10-15%, ±15˜20% of the value). These values are merely examples and are not intended to be limiting. The terms “about” and “substantially” can refer to a percentage of the values as interpreted by those skilled in relevant art(s) in light of the teachings herein.

The fin structures disclosed herein may be patterned by any suitable method. For example, the fin structures may be patterned using one or more photolithography processes, including double-patterning or multi-patterning processes. Double-patterning or multi-patterning processes can combine photolithography and self-aligned processes, allowing patterns to be created that have, for example, pitches smaller than what is otherwise obtainable using a single, direct photolithography process. For example, a sacrificial layer is formed over a substrate and patterned using a photolithography process. Spacers are formed alongside the patterned sacrificial layer using a self-aligned process. The sacrificial layer is then removed, and the remaining spacers may then be used to pattern the fin structures.

The present disclosure provides example gate structures with diffusion barrier layers in FETs (e.g., FinFETs and MOSFETs) and example methods for forming such FETs to improve threshold voltage control in the FETs. In some embodiments, the example gate structure of a FET can include a high-k gate oxide layer, first and second diffusion barrier layers disposed on the high-k gate oxide layer, and a gate metal fill layer disposed on the first and second diffusion barrier layers. In some embodiments, the first and second diffusion barrier layers can be arranged to prevent or minimize the diffusion of metal atoms from the gate metal fill layer to the high-k gate oxide layer. The presence of such diffused metal atoms in the high-k gate oxide layer can cause threshold voltage variations in the FET, and consequently, degrade the device performance. In some embodiments, the first diffusion barrier layer can be formed to have an amorphous structure and a structural density that can limit the concentration of metal atoms diffused from the gate metal fill layer into the first diffusion barrier layer to be at or below about 10 atomic %. Similarly, the second diffusion barrier layer can be formed to have an amorphous structure and a structural density that limit the concentration of metal atoms diffused from the gate metal fill layer into the second diffusion barrier layer to be between about 10 atomic % and about 50 atomic %. Within these concentration limitations, the diffusion of the metal atoms into the high-k gate oxide layer can be prevented or minimized.

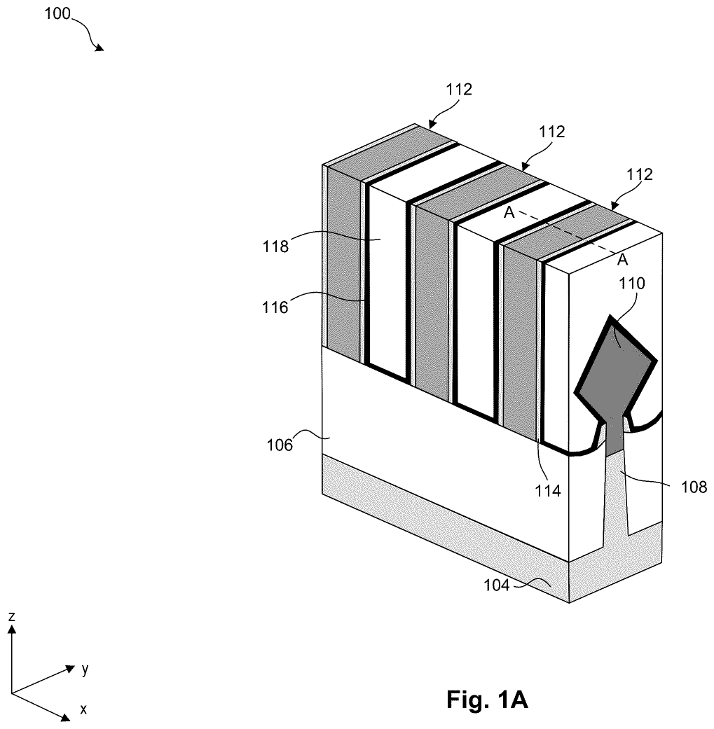

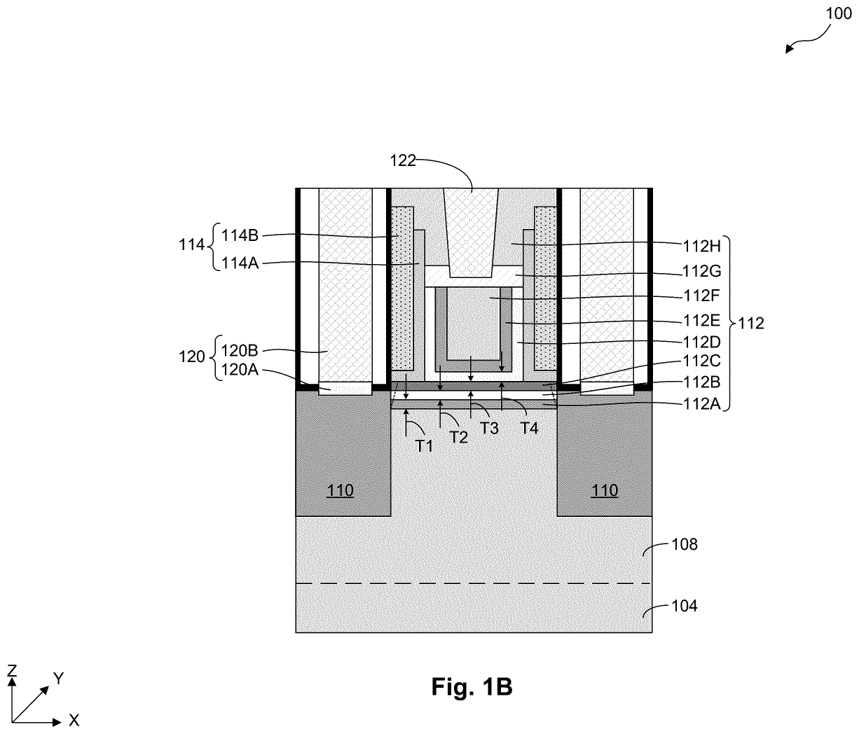

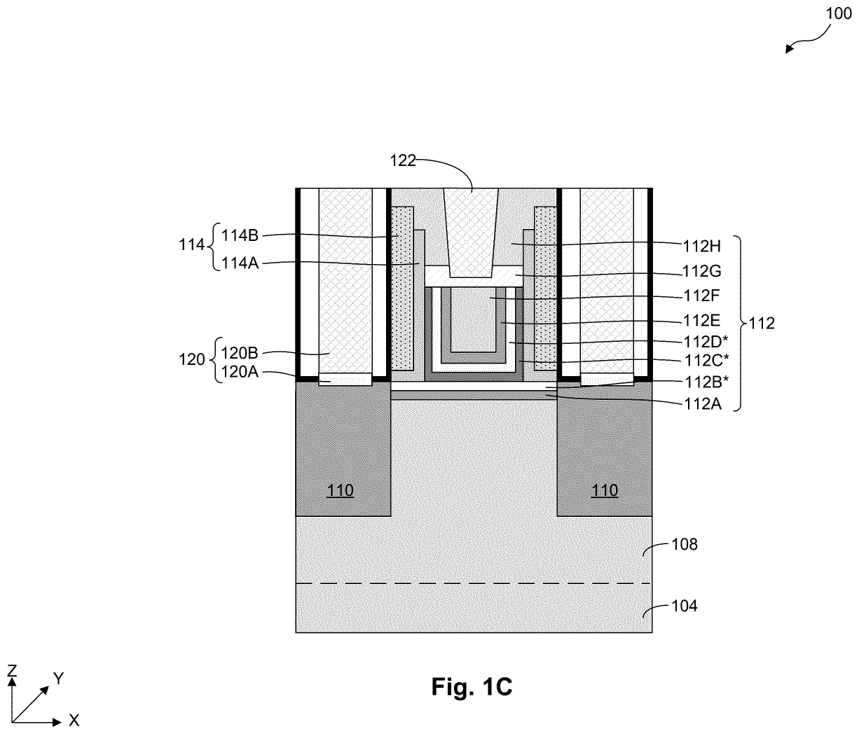

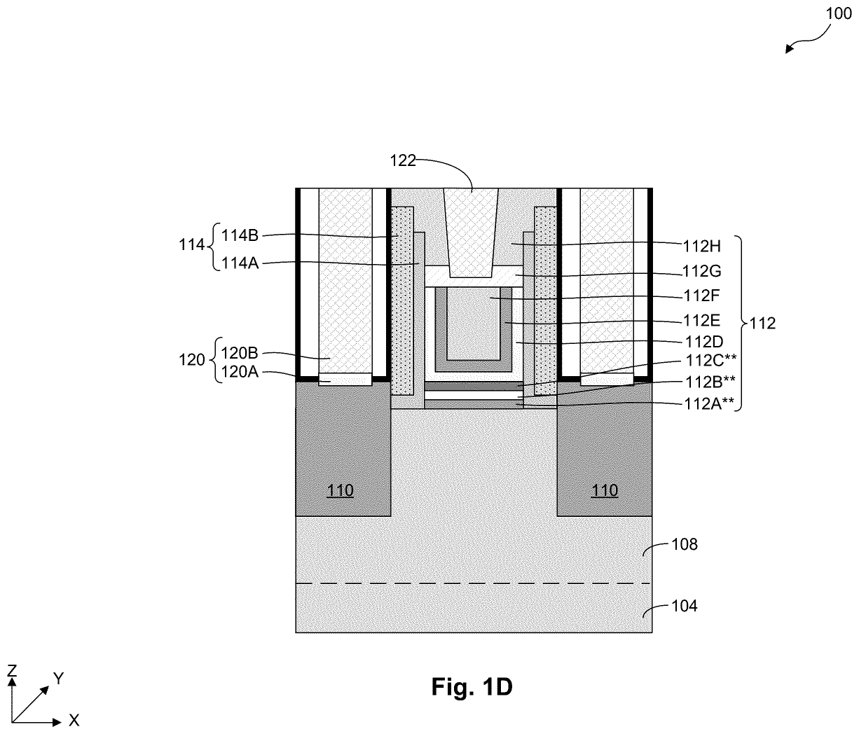

FIG. 1A illustrates an isometric view of a semiconductor device 100, according to some embodiments. In some embodiments, semiconductor device 100 can represent a FinFET and can be referred to as “FinFET 100.” FIGS. 1B, 1C, and 1D illustrate different cross-sectional views of semiconductor device 100, along line A-A of FIG. 1A, according to some embodiments. FIGS. 1B, 1C, and 1D illustrate cross-sectional views with additional structures that are not shown in FIG. 1A for simplicity. The discussion of elements in FIGS. 1A-1D with the same annotations applies to each other, unless mentioned otherwise.

Referring to FIGS. 1A and 1B, in some embodiments, semiconductor device 100 can include (i) a substrate 104, (ii) shallow trench isolation (STI) regions 106 disposed on substrate 104, (iii) fin structure 108 disposed on substrate 104, (iv) S/D regions 110 disposed on fin structure 108, (v) gate structures 112 surrounding portions of fin structure 108 extending above STI regions 106, (vi) gate spacers 114 disposed along sidewalls of gate structures 112, (vii) etch stop layers (ESLs) 116 disposed directly on S/D regions 110, (viii) ILD layers 118 disposed directly on ESLs 116, (ix) S/D contact structures 120 disposed on S/D regions 110, and (x) gate contact structures 122 disposed on gate structures 112.

Semiconductor device 100 can be formed on a substrate 104. In some embodiments, substrate 104 can be a semiconductor material, such as silicon, germanium (Ge), silicon germanium (SiGe), a silicon-on-insulator (SOI) structure, and a combination thereof. Further, substrate 104 can be doped with p-type dopants (e.g., boron, indium, aluminum, or gallium) or n-type dopants (e.g., phosphorus or arsenic). In some embodiments, STI regions 106 can include an insulating material, such as silicon oxide (SiO₂), silicon nitride (SiN), silicon oxynitride (SiON), silicon oxycarbide (SiOC), silicon carbon nitride (SiCN), silicon oxycarbon nitride (SiOCN), and silicon germanium oxide (SiGeOₓ).

In some embodiments, fin structure 108 can include a material similar to substrate 104. Fin structure 108 can have elongated sides extending along an X-axis. S/D regions 110 can include an epitaxially-grown semiconductor material, such as Si, and n-type dopants, such as phosphorus and other suitable n-type dopants for n-type FinFET 100. S/D regions 110 can include an epitaxially-grown semiconductor material, such as Si and SiGe, and p-type dopants, such as boron and other suitable p-type dopants for p-type FinFET 100. S/D regions 110 may refer to a source or a drain, individually or collectively, dependent upon the context.

Gate structure 112 can be a multi-layered structure and can include (i) an interfacial oxide (IL) layer 112A, (ii) a high-k (HK) gate oxide layer 112B, (iii) a first diffusion barrier layer 112C, (iv) a second diffusion barrier layer 112D, (v) a work function metal (WFM) layer 112E, (vi) a gate metal fill layer 112F, (vii) a conductive capping layer 112G, and (viii) an insulating capping layer 112H.

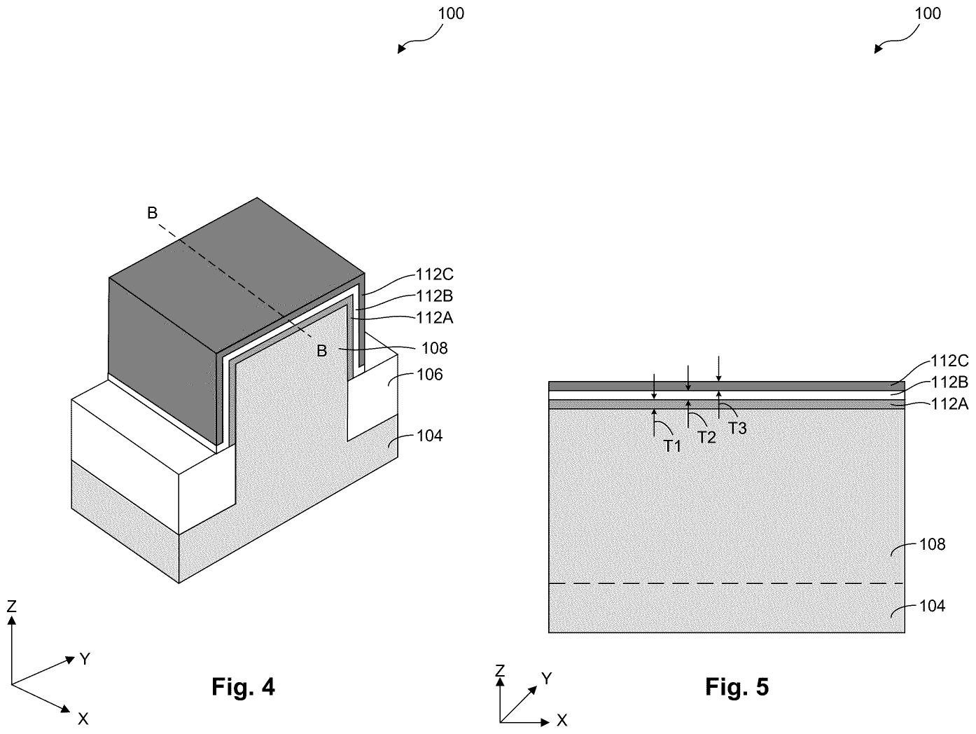

In some embodiments, IL layer 112A can be disposed directly on the portions of fin structure 108 extending above STI regions 106, as described below with reference to FIGS. 4-6. In some embodiments, IL layer 112A can include SiO₂, SiGeOₓ, or germanium oxide (GeOₓ) and can have a thickness T1 of about 1 nm to about 20 nm. In some embodiments, HK gate oxide layer 112B can be disposed directly on IL layer 112A, and overlies on the portions of fin structure 108 extending above STI regions 106, as described below with reference to FIGS. 4-6. In some embodiments, HK gate oxide layer 112B can include a high-k dielectric material, such as hafnium oxide (HfO₂), titanium oxide (TiO₂), hafnium zirconium oxide (HfZrO), tantalum oxide (Ta₂O₃), hafnium silicate (HfSiO₄), zirconium oxide (ZrO₂), and zirconium silicate (ZrSiO₂) and can have a thickness T2 of about 1 nm to about 50 nm. In some embodiments, sidewalls of IL layer 112A and HK gate oxide layer 112B can be vertical, as shown with solid lines in FIG. 1B, or can be tapered, as shown with dashed lines in FIG. 1B. In some embodiments, the sidewalls of IL layer 112A and HK gate oxide layer 112B can be in contact with sidewalls of S/D regions 110.

In some embodiments, first diffusion barrier layer 112C can be disposed directly on HK gate oxide layer 112B, and overlies on the portions of fin structure 108 extending above STI regions 106, as described below with reference to FIGS. 4-6. In some embodiments, first diffusion barrier layer 112C can include a metal nitride layer, such as a titanium nitride (TiN) layer with metal atoms as dopants in the metal nitride layer. The metal atoms diffuse from gate metal fill layer 112F into first diffusion barrier layer 112C through WFM layer 112E and second diffusion barrier layer 112D. In some embodiments, the metal atoms can include aluminum (Al) atoms when gate metal fill layer 112F includes an Al layer.

In some embodiments, first diffusion barrier layer 112C can be arranged to prevent or minimize the diffusion of these metal atoms from gate metal fill layer 112F into HK gate oxide layer 112B. The presence of such diffused metal atoms in HK gate oxide layer 112B can cause threshold voltage variations in semiconductor device 100, and consequently, degrade the device performance. To prevent or minimize such diffusion of metal atoms, first diffusion barrier layer 112C can be formed in an atomic layer deposition (ALD) process or a chemical vapor deposition (CVD) process (described below) to have an amorphous structure and a structural density that can limit the concentration of metal atoms diffused from gate metal fill layer 112F into first diffusion barrier layer 112C to be at or below about 10 atomic %. By limiting the concentration of the diffused metal atoms to be at or below about 10 atomic %, the diffusion of the metal atoms into HK gate oxide layer 112B can be prevented or minimized. In some embodiments, first diffusion barrier layer 112C can include a conductive metal nitride, such as TiN with a Ti concentration of about 30 atomic % to about 70 atomic % and an Al dopant concentration of about 1 atomic % to about 10 atomic %. In some embodiments, sidewalls of first diffusion barrier layer 112C can be vertical, as shown with solid lines in FIG. 1B or can be tapered, as shown with dashed lines in FIG. 1B. In some embodiments, the sidewalls of first diffusion barrier layer 112C can be in contact with sidewalls of ESLs 116 and are not in contact with S/D regions 110.

In some embodiments, second diffusion barrier layer 112D can be disposed directly on first diffusion barrier layer 112C, and can have a U-shaped cross-sectional profile. In some embodiments, second diffusion barrier layer 112D can include a metal nitride layer, such as a tantalum nitride (TaN) layer that is different from the metal nitride layer of first diffusion barrier layer 112C. Similar to first diffusion barrier layer 112C, the metal nitride layer of second diffusion barrier layer 112D can include metal atoms as dopants, which are diffused from gate metal fill layer 112F through WFM layer 112E. In some embodiments, the metal atoms can include Al atoms when gate metal fill layer 112F includes an Al layer.

In some embodiments, in addition to first diffusion barrier layer 112C, second diffusion barrier layer 112D can be arranged to prevent or minimize the diffusion of metal atoms from gate metal fill layer 112F into HK gate oxide layer 112B. Similar to first diffusion barrier layer 112C, second diffusion barrier layer 112D can be formed in an ALD process or a CVD process (described below) to have an amorphous structure and a structural density that can limit the concentration of metal atoms diffused from gate metal fill layer 112F into second diffusion barrier layer 112D to be between about 10 atomic % and about 50 atomic %. By limiting the concentration of the diffused metal atoms to be between about 10 atomic % and about 50 atomic %, the concentration of the diffused metal atoms in first diffusion barrier layer 112C can be limited to be at or below 10 atomic %, which in turn can prevent or minimize the diffusion of the metal atoms into HK gate oxide layer 112B. In some embodiments, second diffusion barrier layer 112D can have a thickness T4 greater than thickness T3 of first diffusion barrier layer 112C. In some embodiments, thicknesses T3 and T4 can be about 2 nm to about 10 nm. Within this range of thicknesses, the diffusion of the metal atoms into HK gate oxide layer 112B can be adequately prevented or minimized without compromising the device size and manufacturing cost.

In some embodiments, WFM layer 112E can include Ti, titanium aluminum (TiAl), titanium aluminum carbide (TiAlC), tantalum aluminum (TaAl), or tantalum aluminum carbide (TaAlC). In some embodiments, WFM layer 112E can include an alloy of Ti and Al. In some embodiments, gate metal fill layer 112F can include a suitable conductive material, such as tungsten (W), Ti, silver (Ag), ruthenium (Ru), molybdenum (Mo), copper (Cu), cobalt (Co), Al, iridium (Ir), nickel (Ni), metal alloys, and a combination thereof.

In some embodiments, insulating capping layer 112H can be disposed directly on conductive capping layer 112G. Insulating capping layer 112H can protect the underlying conductive capping layer 112G from structural and/or compositional degradation during subsequent processing of semiconductor device 100. In some embodiments, insulating capping layer 112H can include a nitride material, such as SiN, and can have a thickness of about 5 nm to about 10 nm for adequate protection of the underlying conductive capping layer 112G.

In some embodiments, conductive capping layer 112G can be disposed directly on second diffusion barrier layer 112D, WFM layer 112E, and gate metal fill layer 112F. Conductive capping layer 112G can provide a conductive interface between gate metal fill layer 112F and gate contact structure 122 to electrically connect gate metal fill layer 112F to gate contact structure 122 without forming gate contact structure 122 directly on or in gate metal fill layer 112F. Gate contact structure 122 is not formed directly on or in gate metal fill layer 112F to prevent contamination by any of the processing materials used in the formation of gate contact structure 122. Contamination of gate metal fill layer 112F can lead to the degradation of device performance. Thus, with the use of conductive capping layer 112G, gate structure 112 can be electrically connected to gate contact structure 122 without compromising the integrity of gate structure 112. In some embodiments, conductive capping layer 112G can include a metallic material, such as W, Ru, Mo, Co, other suitable metallic materials, and a combination thereof.

In some embodiments, gate structure 112 can be electrically isolated from adjacent S/D regions 110 by gate spacers 114. In some embodiments, each gate spacer 114 can be disposed directly on first diffusion barrier layer 112C and overlies on portions of HK gate oxide layer 112B and IL layer 112A. In some embodiments, gate spacer 114 can include a nitride spacer 114A and an oxide spacer 114B. In some embodiments, nitride spacer 114A can have an L-shaped cross-sectional profile. In some embodiments, a horizontal portion of nitride spacer 114A can be disposed directly on first diffusion barrier layer 112C and a vertical portion of nitride spacer 114A can be disposed directly along sidewalls of second diffusion barrier layer 112D. In some embodiments, oxide spacer 114B can be disposed directly on nitride spacer 114A. In some embodiments, nitride spacer 114A can include silicon nitride (SiNₓ) and may not include an oxide material. In some embodiments, oxide spacer 114B can include silicon oxide (SiOₓ) and may not include a nitride material.

In some embodiments, ESLs 116 can be disposed directly on S/D regions 110 (shown in FIG. 1A; not visible in cross-sectional view of FIG. 1B). In some embodiments, ESLs 116 can have a dielectric constant of about 4 to about 7 and can include a dielectric material, such as lanthanum oxide (LaO), aluminum oxide (Al₂O₃), yttrium oxide (Y₂O₃), tantalum carbon nitride (TaCN), zirconium silicide (ZrSi), SiOCN, SiOC, SiCN, zirconium nitride (ZrN), zirconium aluminum oxide (ZrAlO), TiO₂, Ta₂O₃, ZrO₂, HfO₂, SiN, hafnium silicide (HfSi), aluminum oxynitride (AlON), SiO₂, SiC, SiN, and zinc oxide (ZnO). In some embodiments, ILD layers 118 can be disposed directly on ILD layers 118 (shown in FIG. 1A; not visible in cross-sectional view of FIG. 1B). In some embodiments, ILD layers 118 can include an insulating material, such as SiO₂, SiN, SiON, SiCN, and SiOCN. In some embodiments, top surfaces of ILD layers 118, ESL 116, and insulating capping layer 112H can be substantially coplanar with each other.

In some embodiments, S/D contact structure 120 can include (i) silicide layers 120A disposed in S/D regions 110, and (ii) contact plugs 120B disposed on silicide layers 120A. In some embodiments, silicide layer 120A in n-type FinFET 100 can include titanium silicide (TiₓSi_{y}), tantalum silicide (TaₓSi_{y}), molybdenum (MoₓSi_{y}), zirconium silicide (ZrₓSi_{y}), hafnium silicide (HfₓSi_{y}), scandium silicide (ScₓSi_{y}), yttrium silicide (YₓSi_{y}), terbium silicide (TbₓSi_{y}), lutetium silicide (LuₓSi_{y}), erbium silicide (ErₓSi_{y}), ybtterbium silicide (YbₓSi_{y}), europium silicide (EuₓSi_{y}), thorium silicide (ThₓSi_{y}), other suitable metal silicide materials, or a combination thereof. In some embodiments, silicide layer 120A in p-type FinFET 100 can include nickel silicide (NiₓSi_{y}), cobalt silicide (CoₓSi_{y}), manganese silicide (MnₓSi_{y}), tungsten silicide (WₓSi_{y}), iron silicide (FeₓSi_{y}), rhodium silicide (RhₓSi_{y}), palladium silicide (PdₓSi_{y}), ruthenium silicide (RuₓSi_{y}), platinum silicide (PtₓSi_{y}), iridium silicide (IrₓSi_{y}), osmium silicide (OsₓSi_{y}), other suitable metal silicide materials, or a combination thereof. In some embodiments, contact plugs 120B can include conductive materials with low resistivity (e.g., resistivity of about 50 μΩ-cm, about 40μΩ-cm, about 30μΩ-cm, about 20μΩ-cm, or about 10μΩ-cm), such as Co, W, Ru, Al, Mo, iridium (Ir), nickel (Ni), Osmium (Os), rhodium (Rh), other suitable conductive materials with low resistivity, and a combination thereof. In some embodiments, gate contact structure 122 can include a conductive material similar to that of contact plug 120B.

Referring to FIG. 1C, in some embodiments, semiconductor device 100 can have HK gate oxide layer 112B*, first diffusion barrier layer 112C*, and second diffusion barrier layer 112D*, instead of HK gate oxide layer 112B, first diffusion barrier layer 112C, and second diffusion barrier layer 112D of FIG. 1B. The discussion of HK gate oxide layer 112B, first diffusion barrier layer 112C, and second diffusion barrier layer 112D applies to HK gate oxide layer 112B*, first diffusion barrier layer 112C*, and second diffusion barrier layer 112D*, respectively, unless mentioned otherwise. In some embodiments, first diffusion barrier layer 112C* is disposed between spacers 114, as shown in FIG. 1C, and not disposed under spacers 114 as first diffusion barrier layer 112C shown in FIG. 1B. As a result, the horizontal portions of nitride spacers 114A are disposed directly on HK gate oxide layer 112B* and the vertical portions of nitride spacers 114A are disposed directly along sidewalls of first diffusion barrier layer 112C*. In some embodiments, similar to second diffusion barrier layer 112D*, first diffusion barrier layer 112C* can have a U-shaped cross-sectional profile, instead of the linear profile shown in FIG. 1B. The vertical portions of second diffusion barrier layer 112D* are disposed directly on the vertical portions of first diffusion barrier layer 112C* and the horizontal portion of second diffusion barrier layer 112D* is disposed directly on the horizontal portion of first diffusion barrier layer 112C*.

Referring to FIG. 1D, in some embodiments, semiconductor device 100 can have IL layer 112A*, HK gate oxide layer 112B*, and first diffusion barrier layer 112C*, instead of IL layer 112A, HK gate oxide layer 112B, and first diffusion barrier layer 112C of FIG. 1B. The discussion of IL layer 112A, HK gate oxide layer 112B, and first diffusion barrier layer 112C applies to IL layer 112A*, HK gate oxide layer 112B*, and first diffusion barrier layer 112C*, respectively, unless mentioned otherwise. In some embodiments, the stack of IL layer 112A*, HK gate oxide layer 112B*, and first diffusion barrier layer 112C* is disposed between spacers 114, as shown in FIG. 1D, and not disposed under spacers 114 as the stack of IL layer 112A, HK gate oxide layer 112B, and first diffusion barrier layer 112C shown in FIG. 1B. As a result, nitride spacers 114A are disposed directly on fin structure 108 and sidewalls of IL layer 112A*, HK gate oxide layer 112B*, and first diffusion barrier layer 112C* are in contact with sidewalls of nitride spacers 114A.

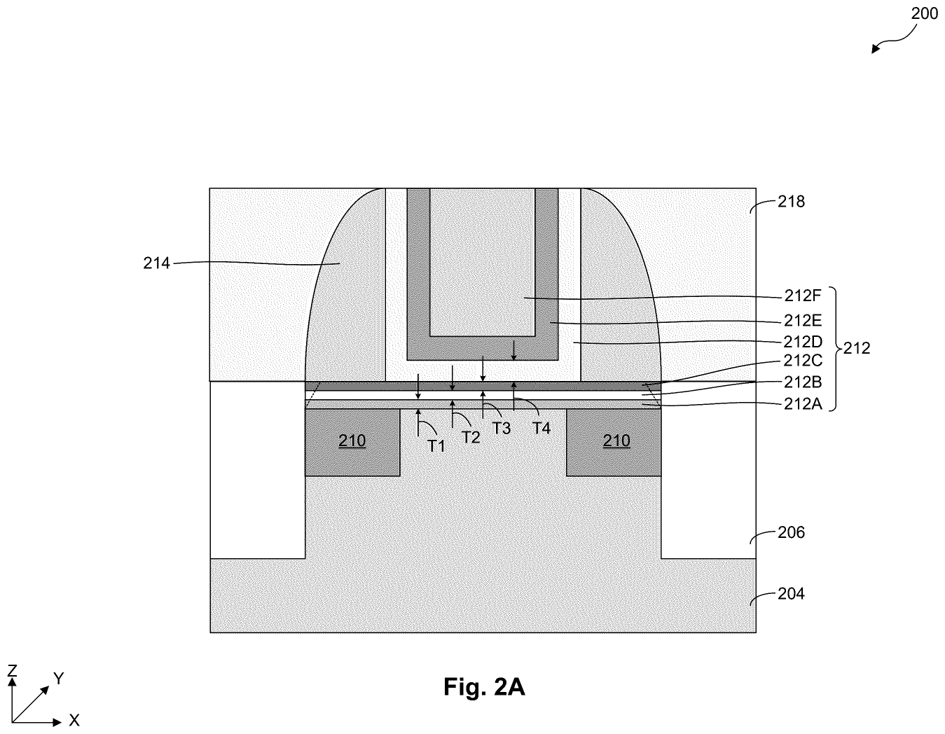

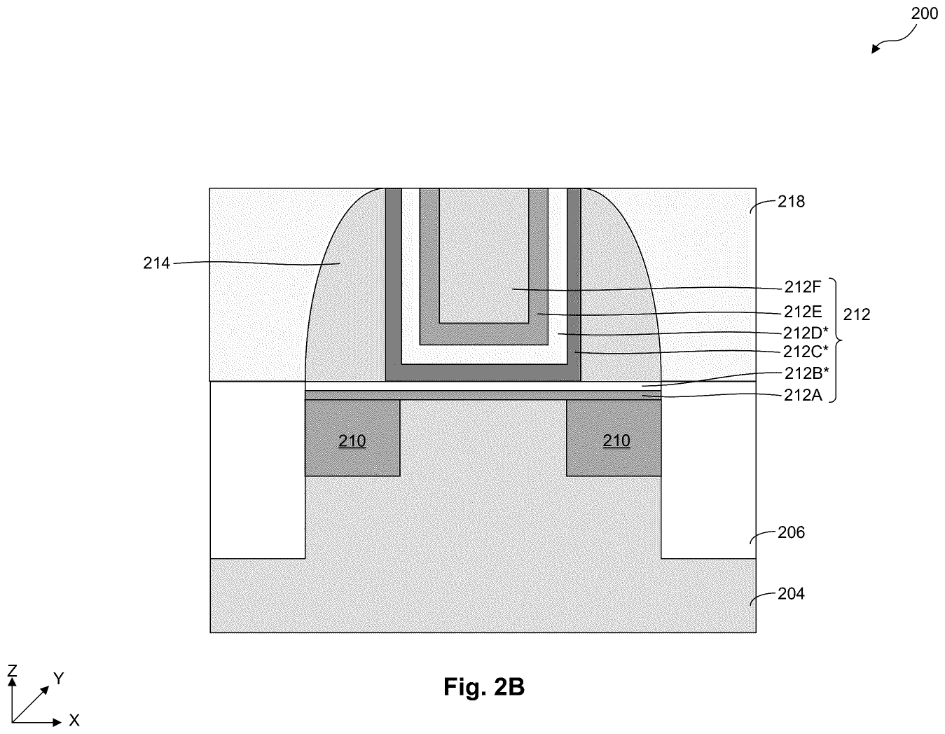

FIGS. 2A and 2B illustrate different cross-sectional views of a semiconductor device 200, according to some embodiments. In some embodiments, semiconductor device 200 can represent a MOSFET and can be referred to as “MOSFET 200.” The discussion of elements in FIGS. 2A and 2B with the same annotations applies to each other, unless mentioned otherwise.

Referring to FIG. 2A, in some embodiments, semiconductor device 200 can include (i) a substrate 204, (ii) STI regions 206 disposed on substrate 204, (iii) S/D regions 210 disposed in substrate 204, (iv) gate structure 212 disposed on substrate 204, (v) gate spacers 214 disposed along sidewalls of gate structure 212, (vi) ILD layers 118 disposed directly on gate spacers 214 and STI regions 206. The discussion of substrate 104, STI regions 106, and ILD layers 118 applies to substrate 204, STI regions 206, and ILD layers 218, unless mentioned otherwise.

In some embodiments, S/D regions 210 can include doped regions in substrate 204. Doped regions can include n-type dopants, such as phosphorus and other suitable n-type dopants for n-type MOSFET 200 or p-type dopants, such as boron and other suitable p-type dopants for p-type MOSFET 200.

Gate structure 212 can be a multi-layered structure and can include (i) an IL layer 212A, (ii) a HK gate oxide layer 212B, (iii) a first diffusion barrier layer 212C, (iv) a second diffusion barrier layer 212D, (v) a WFM layer 212E, and (vi) a gate metal fill layer 212F. The discussion of IL layer 112A, HK gate oxide layer 112B, first diffusion barrier layer 112C, second diffusion barrier layer 112D, WFM layer 112E, and gate metal fill layer 112F applies to IL layer 212A, HK gate oxide layer 212B, first diffusion barrier layer 212C, second diffusion barrier layer 212D, WFM layer 212E, and gate metal fill layer 212F, respectively, unless mentioned otherwise.

Referring to FIG. 2B, in some embodiments, semiconductor device 200 can have HK gate oxide layer 212B*, first diffusion barrier layer 212C*, and second diffusion barrier layer 212D*, instead of HK gate oxide layer 212B, first diffusion barrier layer 212C, and second diffusion barrier layer 212D of FIG. 2A. The discussion of HK gate oxide layer 212B, first diffusion barrier layer 212C, and second diffusion barrier layer 212D applies to HK gate oxide layer 212B*, first diffusion barrier layer 212C*, and second diffusion barrier layer 212D*, respectively, unless mentioned otherwise. In some embodiments, first diffusion barrier layer 212C* is disposed between spacers 214, as shown in FIG. 2B, and not disposed under spacers 214 as first diffusion barrier layer 212C shown in FIG. 2A. As a result, the bottom surfaces of gate spacers 214 are disposed directly on HK gate oxide layer 112B* and the sidewalls of gate spacers 214 are disposed directly along sidewalls of first diffusion barrier layer 212C*. In some embodiments, similar to second diffusion barrier layer 212D*, first diffusion barrier layer 212C* can have a U-shaped cross-sectional profile, instead of the linear profile shown in FIG. 2A. The vertical portions of second diffusion barrier layer 212D* are disposed directly on the vertical portions of first diffusion barrier layer 212C* and the horizontal portion of second diffusion barrier layer 212D* is disposed directly on the horizontal portion of first diffusion barrier layer 212C*.

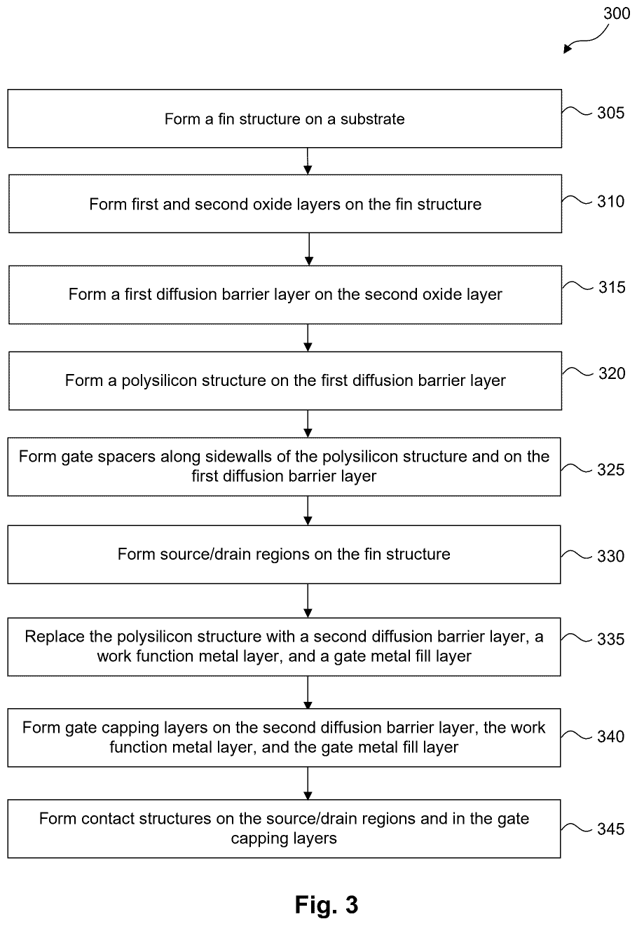

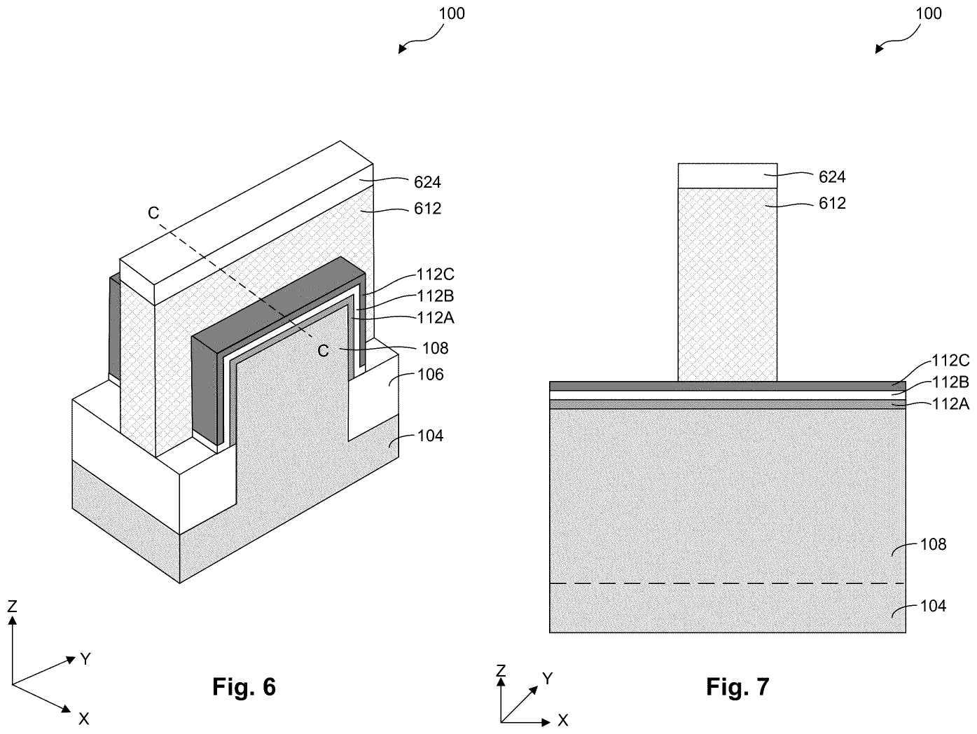

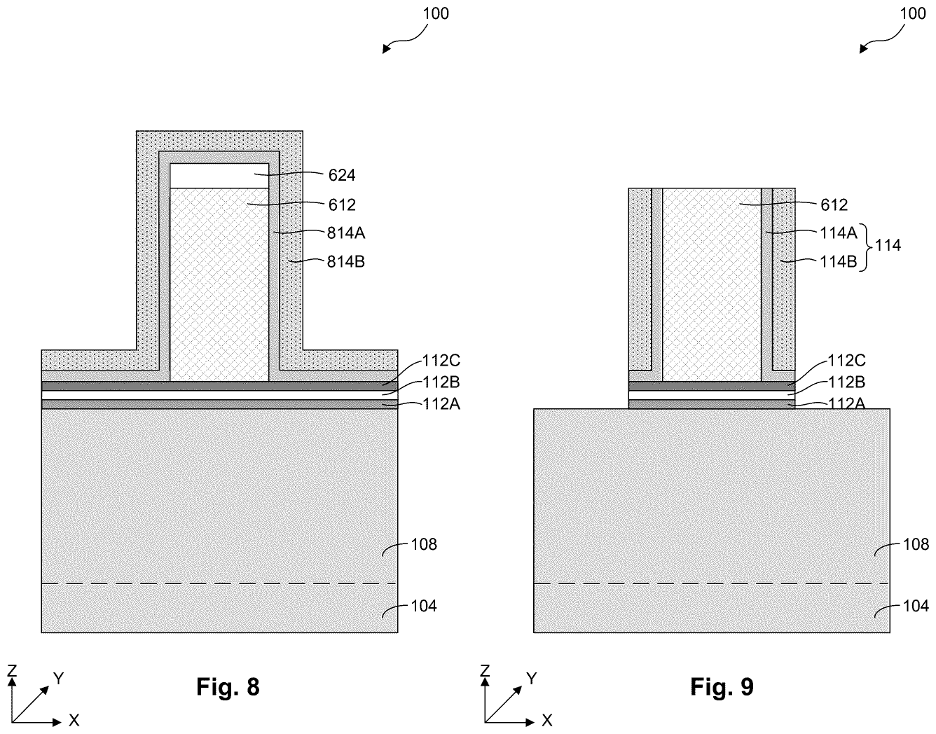

FIG. 3 is a flow diagram of an example method 300 for fabricating semiconductor device 100 with the cross-sectional view of FIG. 1B, according to some embodiments. For illustrative purposes, the operations illustrated in FIG. 3 will be described with reference to the example fabrication process for fabricating semiconductor device 100 as illustrated in FIGS. 4-16. FIG. 4 is an isometric view of semiconductor device 100 and FIG. 5 is a cross-sectional view of semiconductor device 100 along line B-B of FIG. 4 at a stage of fabrication of semiconductor device 100, according to some embodiments. FIG. 6 is an isometric view of semiconductor device 100 and FIG. 7 is a cross-sectional view of semiconductor device 100 along line C-C of FIG. 6 at another stage of fabrication of semiconductor device 100, according to some embodiments. FIGS. 8-16 are cross-sectional views of semiconductor device 100 along line A-A of FIG. 1A at various stages of fabrication of semiconductor device 100, according to some embodiments. Operations can be performed in a different order or not performed depending on specific applications. It should be noted that method 300 may not produce a complete semiconductor device 100. Accordingly, it is understood that additional processes can be provided before, during, and after method 300, and that some other processes may only be briefly described herein. The discussion of elements in FIGS. 1A-1D and 4-16 with the same annotations applies to each other, unless mentioned otherwise.

Referring to FIG. 3, in operation 305, a fin structure is formed on a substrate. For example, as described with reference to FIGS. 4 and 5, fin structure 108 is formed on substrate 104. In some embodiments, the formation of fin structure 108 can include patterning substrate 104 using one or more photolithography processes, including double-patterning or multi-patterning processes. The formation of fin structure 108 can be followed by the formation of STI regions 106, as shown in FIG. 4.

Referring to FIG. 3, in operation 310, first and second oxide layers are formed on the fin structure. For example, as described with reference to FIGS. 4 and 5, IL layer 112A (also referred to as “first oxide layer 112A”) and HK gate oxide layer 112B (also referred to as “second oxide layer 112B”) are formed on fin structure 108. In some embodiments, the formation of IL layer 112A can include performing an oxidation process on the surfaces of fin structure 108 that are exposed above STI regions 106. In some embodiments, the oxidation process can be performed in an oxidizing ambient at a temperature of about 30° C. to about 200° C. or at other suitable oxidation temperatures. In some embodiments, the oxidizing ambient can include a combination of ozone (O₃), a mixture of ammonia hydroxide, hydrogen peroxide, and water, and/or a mixture of hydrochloric acid, hydrogen peroxide, and water. In some embodiments, the oxidation process can be performed in an oxygen ambient or in a steam and oxygen ambient at a temperature of about 400° C. to about 600° C.

In some embodiments, the formation of HK gate oxide layer 112B can include depositing an oxide layer having a high-k dielectric material, such as hafnium oxide (HfO₂), titanium oxide (TiO₂), hafnium zirconium oxide (HfZrO), tantalum oxide (Ta₂O₃), zirconium oxide (ZrO₂), and zirconium silicate (ZrSiO₂) on IL layer 112A. In some embodiments, the portions of the oxide layer (not shown) on STI regions 106 that are not covered by first diffusion barrier layer 112C can be etched after the formation of first diffusion barrier layer 112C in subsequent operation 315 to form HK gate oxide layer 112B, as shown in FIGS. 4 and 5.

Referring to FIG. 3, in operation 315, a first diffusion barrier layer is formed on the second oxide layer. For example, as described with reference to FIGS. 4 and 5, first diffusion barrier layer 112C is formed on HK gate oxide layer 112B. In some embodiments, the formation of first diffusion barrier layer 112C can include depositing two or more monolayers of a metal nitride (not shown) on HK gate oxide layer 112B. Each metal nitride monolayer can be deposited in an ALD cycle. In some embodiments, the total thickness of the metal nitride layer deposited on HK gate oxide layer 112B can be measured after the deposition of each metal nitride monolayer. The ALD process can be terminated after the desired total thickness T3 of the metal nitride layer is achieved.

The sequential deposition of the metal nitride monolayers can form first diffusion barrier layer 112C with a higher conformity, a higher thickness uniformity (e.g., about 10% to about 50% higher thickness uniformity), and a higher density (e.g., about 10% to about 50% higher density) than similar metal nitride layers formed in physical vapor deposition (PVD) processes with a same thickness as first diffusion barrier layer 112C. The higher density of first diffusion barrier layer 112C can minimize diffusion of metal atoms (e.g., Al atoms) from gate metal fill layer 112F into first diffusion barrier layer 112C and keep the concentration of metal atoms in first diffusion barrier layer 112C at or below about 10 atomic %. In addition, the higher thickness uniformity across first diffusion barrier layer 112C can prevent or minimize structural weaknesses in first diffusion barrier layer 112C through which the metal atoms can diffuse. The structural weaknesses can be present in relatively thinner regions if thickness non-uniformity exists across first diffusion barrier layer 112C. As a result, with such highly dense and highly uniform first diffusion barrier layer 112C, the concentration of metal atoms diffusing into HK gate oxide layer 112B from gate metal fill layer 112F through first diffusion barrier layer 112C can be prevented or minimized to improve device performance.

In some embodiments, the formation of first diffusion barrier layer 112C can include sequential operations of (i) performing an ALD cycle (e.g., one ALD cycle) to deposit the metal nitride monolayer (not shown) on HK gate oxide layer 112B, (ii) performing another ALD cycle (e.g., one ALD cycle) to deposit another metal nitride monolayer (not shown) on the underlying metal nitride monolayer in an ALD process, (iii) measuring the total thickness of the metal nitride layer deposited on HK gate oxide layer 112B, (iv) determining if the measured total thickness is equal to thickness T3, (v) repeating steps (ii)-(iv) if the measured total thickness is less than thickness T3, (vi) terminating the ALD process after thickness T3 of the metal nitride layer is achieved, and (vii) etching the horizontal portions of the metal nitride layer on STI regions 106 to form first diffusion barrier layer 112C, as shown in FIGS. 4 and 5. In some embodiments, the metal nitride layer can be evaluated to determine if it is amorphous after the deposition of each metal nitride monolayer.

In some embodiments, performing the ALD cycle to form each monolayer of the metal nitride layer (e.g., TiN layer) can include sequential operations of (i) flowing a metal precursor gas (e.g., titanium tetrachloride (TiCl₄) on HK gate oxide layer 112B or on the metal nitride monolayer formed in a preceding ALD cycle, (ii) purging to flush out gas phase reactants, (iii) flowing a nitrogen precursor gas (e.g., ammonia (NH₃)) to react with the metal precursor chemisorbed on HK gate oxide layer 112B or on the metal nitride monolayer (e.g., TiN monolayer) formed in the preceding ALD cycle and to form a metal nitride monolayer, and (iv) purging byproducts (e.g., hydrogen chloride (HCl) gas and nitrogen (N) gas) formed during the reaction between the metal and nitrogen precursors. In some embodiments, the chemical reaction between the metal and nitrogen precursors can be represented by a chemical reaction formula: 6TiCl₄+8NH₃→6TiN+24HCl+4N₂. In some embodiments, first diffusion barrier layer 112C can be formed using a CVD process. The parameters (e.g., RF power, DC power, and/or argon and nitrogen flow ratio) of CVD process can be modulated to achieve first diffusion barrier layer 112C with higher density than that achieved in PVD processes.

Referring to FIG. 3, in operation 320, a polysilicon structure is formed on the first diffusion barrier layer. For example, as described with reference to FIGS. 6 and 7, polysilicon structure 612 is formed directly on first diffusion barrier layer 112C. In some embodiments, the formation of polysilicon structure 612 can include sequential operations of (i) depositing a polysilicon layer (not shown) on the structures of FIG. 4, and (ii) performing a patterning process (e.g., lithography process) on the polysilicon layer to form polysilicon structure 612, as shown in FIGS. 6 and 7. In some embodiments, hard mask layer 624 can be formed during the formation of polysilicon structure 612.

Referring to FIG. 3, in operation 325, gate spacers are formed along sidewalls of the polysilicon structure and on the first diffusion barrier layer. For example, as described with reference to FIGS. 8 and 9, gate spacers 114 having spacers 114A and 114B are formed along sidewalls of polysilicon structure 612 and on first diffusion barrier layer 112C. In some embodiments, the formation of gate spacers 114 can include sequential operations of (i) depositing a nitride layer 814A directly on the structures of FIGS. 6 and 7, as shown in FIG. 8, (ii) depositing an oxide layer 814B directly on nitride layer 814A to form the structure of FIG. 8, (iii) performing an anneal process on the structure of FIG. 8 to densify nitride layer 814A, (iv) etching horizontal portions of oxide layer 814B to form spacers 114B, as shown in FIG. 9, and (v) etching portions of densified nitride layer 814A that are exposed after etching of oxide layer 814B to form spacers 114A, as shown in FIG. 9.

Following the formation of gate spacers 114, the portions of IL layer 112A, HK gate oxide layer 112B, and first diffusion barrier layer 112C that are not underlying polysilicon structure 612 and spacers 114 can be removed and surface portions of fin structure 108 can be exposed, as shown in FIG. 9. In some embodiments, the portions of IL layer 112A, HK gate oxide layer 112B, and first diffusion barrier layer 112C can be removed by a wet etch process or a dry etch process.

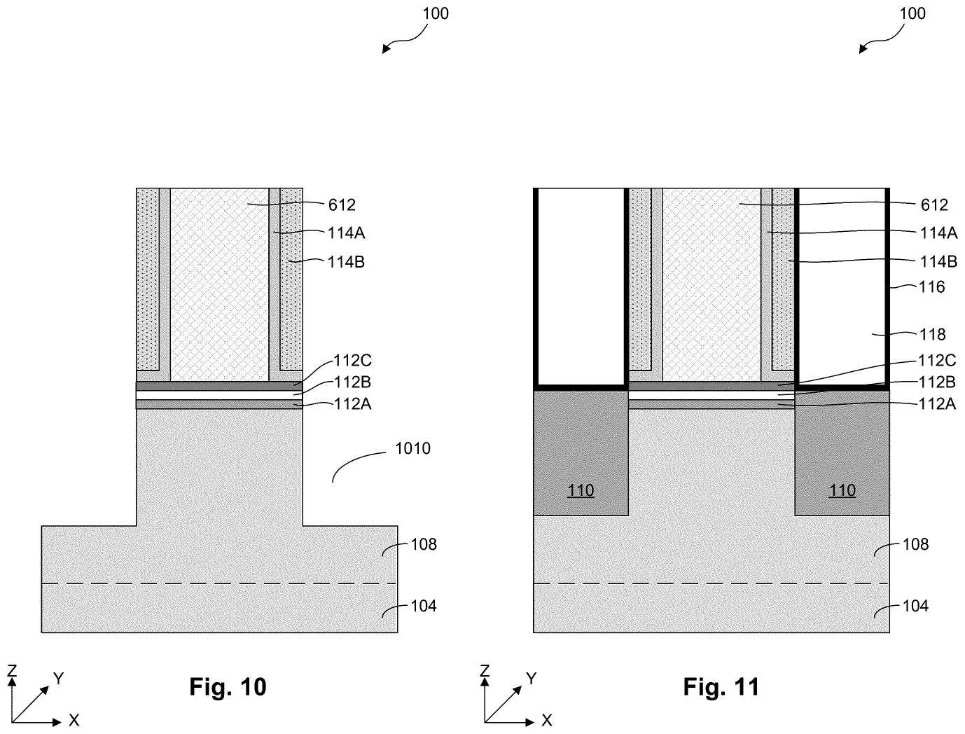

Referring to FIG. 3, in operation 330, S/D regions are formed on the fin structure. For example, as described with reference to FIGS. 10 and 11, S/D regions 110 are formed on fin structure 108. In some embodiments, the formation of S/D regions 110 can include sequential operations of (i) forming S/D openings 1010, as shown in FIG. 10, by etching through the exposed surface portions of fin structure 108 of FIG. 9, and (ii) epitaxially growing a semiconductor material (e.g., Si or SiGe) with n-type or p-type dopants in S/D openings 1010, as shown in FIG. 11. The formation of S/D regions 110 can be followed by the formation of ESLs 116 and ILD layers 118, as shown in FIG. 11.

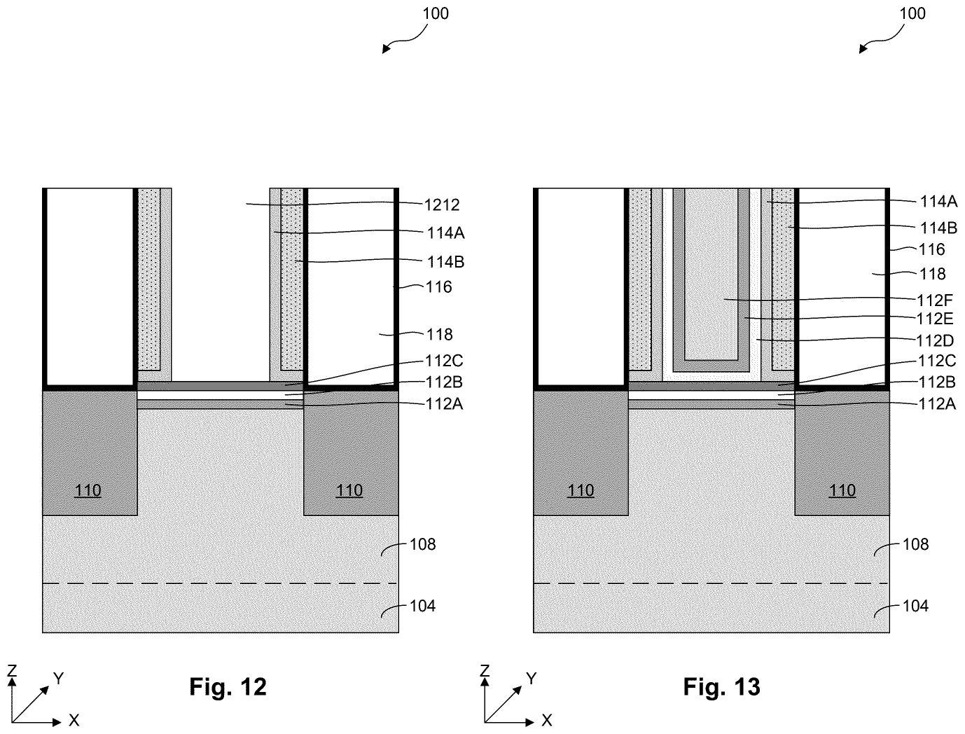

Referring to FIG. 3, in operation 335, the polysilicon structure is replaced with a second diffusion barrier layer, a WFM layer, and a gate metal fill layer. For example, as described with reference to FIGS. 12 and 13, polysilicon structure 612 is replaced with second diffusion barrier layer 112D, WFM layer 112E, and gate metal fill layer 112F. In some embodiments, the replacement of polysilicon structure 612 with second diffusion barrier layer 112D, WFM layer 112E, and gate metal fill layer 112F can include sequential operations of (i) etching polysilicon structure 612 to form gate opening 1212, as shown in FIG. 12, (ii) depositing second diffusion barrier layer 112D in gate opening 1212, (iii) depositing WFM layer 112E on second diffusion barrier layer 112D, (iv) depositing gate metal fill layer 112F on WFM layer 112E, and (v) performing a chemical mechanical polishing (CMP) process to substantially coplanarize top surfaces of second diffusion layer 112D, WFM layer 112E, and gate metal fill layer 112F with top surfaces of ILD layer 118, as shown in FIG. 13.

The deposition of second diffusion barrier layer 112D can include depositing another metal nitride layer (e.g., TaN) different from the metal nitride layer (e.g., TiN) of first diffusion barrier layer 112C. Similar to the process for depositing first diffusion barrier layer 112C, in some embodiments, the deposition of second diffusion barrier layer 112D can include sequential operations of (i) performing an ALD cycle (e.g., one ALD cycle) to deposit a monolayer of TaN (not shown) in gate opening 1212, (ii) performing another ALD cycle (e.g., one ALD cycle) to deposit another TaN monolayer (not shown) on the underlying TaN monolayer, (iii) measuring the total thickness of TaN layer deposited in gate opening 1212, (iv) determining if the measured total thickness is equal to thickness T4, (v) repeating steps (ii)-(iv) if the measured total thickness is less than thickness T4, (vi) terminating the ALD process after thickness T4 of TaN layer is achieved. In some embodiments, the TaN layer can be evaluated to determine if it is amorphous after the deposition of each monolayer. In some embodiments, the ALD cycle for depositing each TaN monolayer can be similar to depositing the TiN monolayer of first diffusion barrier layer 112C in operation 315, except a Ta precursor is used instead of Ti precursor (e.g., TiCl₄). In some embodiments, second diffusion barrier layer 112D can be formed using a CVD process.

The sequential deposition of the monolayers can form second diffusion barrier layer 112D with a higher conformity and a higher density (e.g., about 10% to about 50% higher density) than similar metal nitride layers formed in PVD processes with the same thickness as second diffusion barrier layer 112D. The higher density of second diffusion barrier layer 112D can minimize diffusion of metal atoms (e.g., Al atoms) from gate metal fill layer 112F into second diffusion barrier layer 112D and keep the concentration of the metal atoms in second diffusion barrier layer 112D at or below about 50 atomic %. As a result, the higher density of second diffusion barrier layer 112D in addition to the higher density of first diffusion barrier layer 112C (discussed above) can minimize the concentration of metal atoms diffusing into first diffusion barrier layer 112C from gate metal fill layer 112F through second diffusion barrier layer 112D to at or below about 10 atomic %.

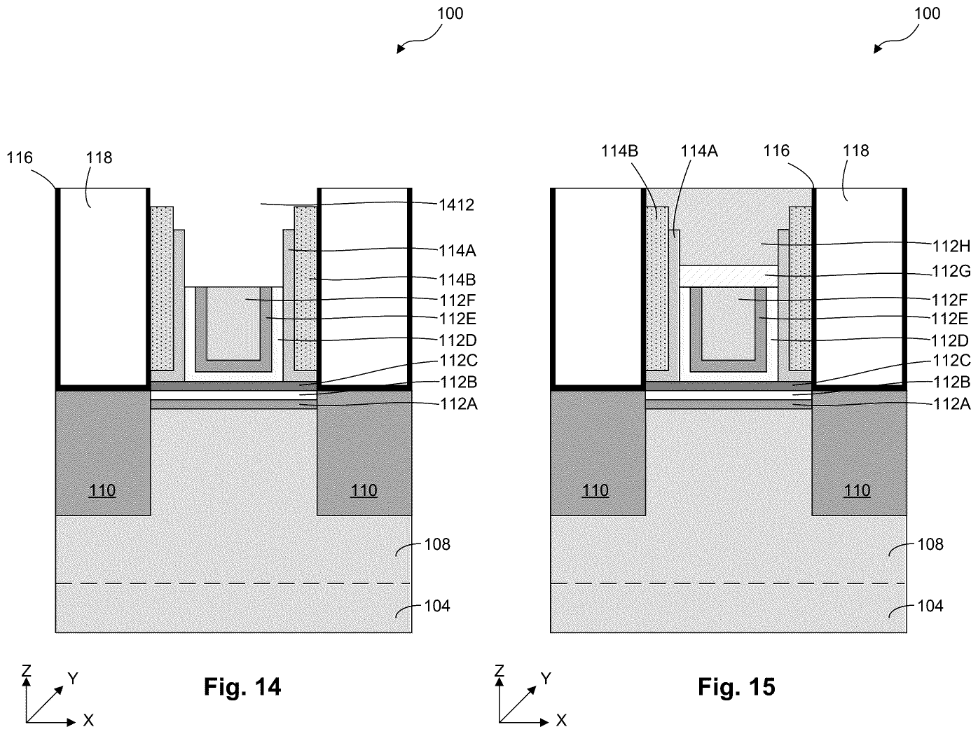

Referring to FIG. 3, in operation 340, gate capping layers are formed on the second diffusion barrier layer, the WFM layer, and the gate metal fill layer. For example, as described with reference to FIGS. 14 and 15, gate capping layers having conductive capping layer 112G and insulation capping layer 112H are formed on second diffusion barrier layer 112D, WFM layer 112E, and gate metal fill layer 112F. In some embodiments, the formation of conductive capping layer 112G can include (i) etching second diffusion barrier layer 112D, WFM layer 112E, and gate metal fill layer 112F to form opening 1412, as shown in FIG. 14, and (ii) depositing the conductive material of conductive capping layer 112G in opening 1412, as shown in FIG. 15. In some embodiments, the formation of insulating capping layer 112H can include (i) depositing the material of insulating capping layer 112H on conductive capping layer 112G to fill opening 1412, and (ii) performing a CMP process on the deposited material of insulating capping layer 112H to substantially coplanarize the top surface of insulating capping layer 112H with top surfaces of ILD layers 118, as shown in FIG. 15.

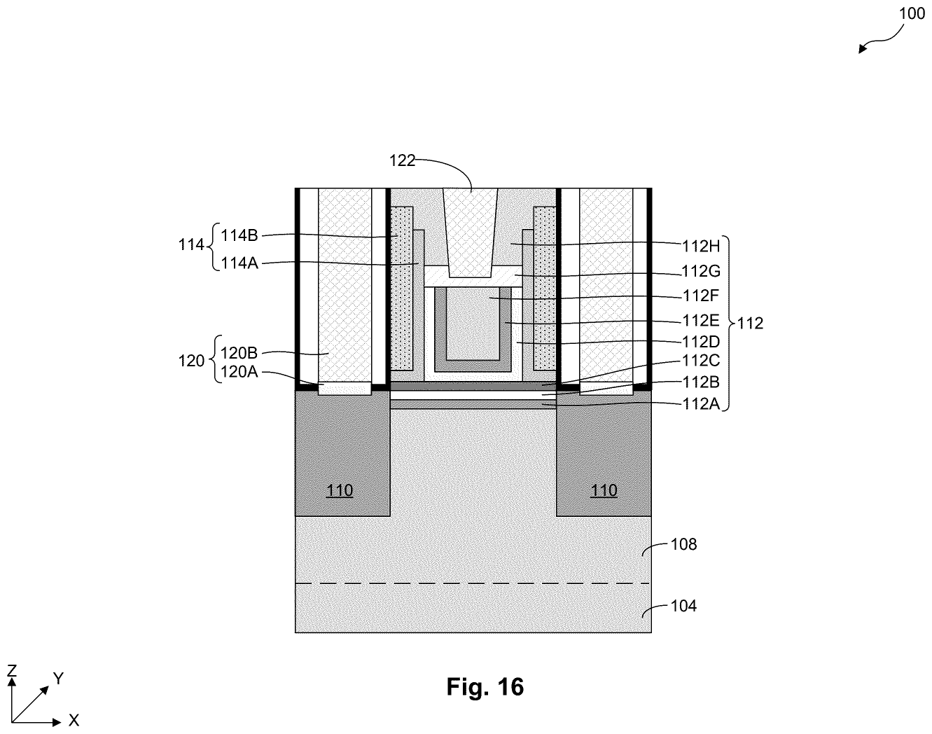

Referring to FIG. 3, in operation 345, contact structures can be formed on the S/D regions and in the gate capping layers. For example, as shown in FIG. 16, S/D contact structures 120 are formed on S/D regions 110 and gate contact structure 122 is formed in conductive capping layer 112G and insulation capping layer 112H.

In some embodiments, semiconductor device 100 with the cross-sectional view of FIG. 1C can be formed using method 300 as described above with reference to FIGS. 3-16, except (i) operation 310 can be followed by operation 320, (ii) polysilicon structure 612 can be formed directly on HK gate oxide layer 112B in operation 320, instead of being formed directly on first diffusion barrier layer 112C in operation 320, (iii) spacers 114A can be formed directly on HK gate oxide layer 112B in operation 325, instead of being formed directly on first diffusion barrier layer 112C in operation 325, (iv) first diffusion barrier layer 112C can be formed in gate opening 1212 after the removal of polysilicon structure 612 and prior to the formation of second diffusion barrier layer 112D in operation 335, instead of being formed in operation 315, and (v) conductive capping layer 112G can be formed directly on first diffusion barrier layer 112C in addition to being formed directly on second diffusion barrier layer 112D, WFM layer 112E, and gate metal fill layer 112F in operation 340.

In some embodiments, semiconductor device 100 with the cross-sectional view of FIG. 1D can be formed using method 300 as described above with reference to FIGS. 3-16, except (i) the portions of IL layer 112A, HK gate oxide layer 112B, and first diffusion barrier layer 112C that are not underlying polysilicon structure 612 and spacers 114A and 114B can be removed after the formation of polysilicon structure 612 in operation 320, instead of being removed after the formation of spacers 114A and 114B in operation 325, and (ii) spacers 114A can be formed directly on fin structure 108 in operation 325, instead of being formed directly on first diffusion barrier layer 112C in operation 325.

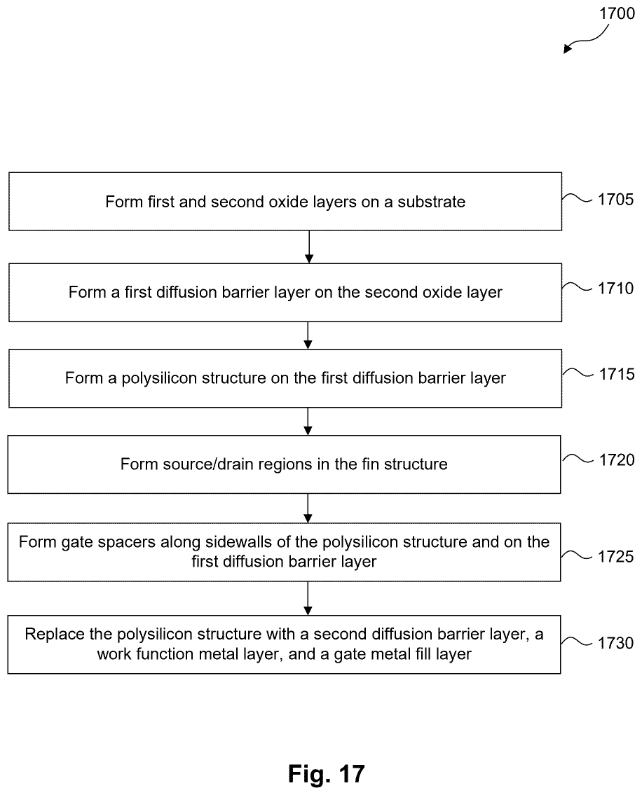

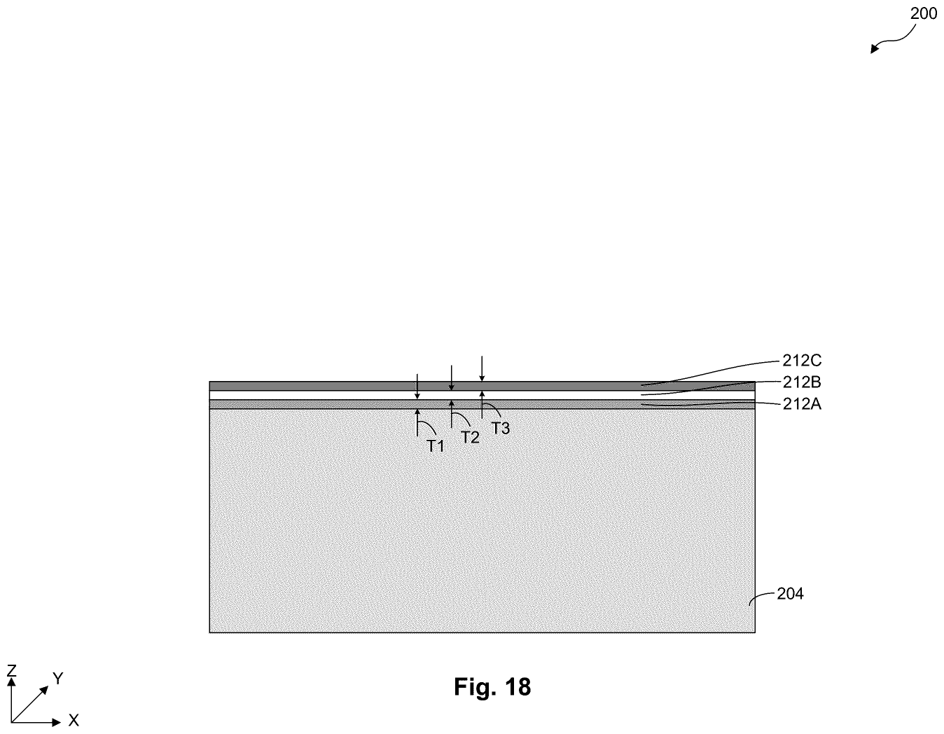

FIG. 17 is a flow diagram of an example method 1700 for fabricating semiconductor device 200 with the cross-sectional view of FIG. 2A, according to some embodiments. For illustrative purposes, the operations illustrated in FIG. 17 will be described with reference to the example fabrication process for fabricating semiconductor device 200 as illustrated in FIGS. 18-22. FIGS. 18-22 are cross-sectional views of semiconductor device 200 at various stages of fabrication of semiconductor device 200, according to some embodiments. Operations can be performed in a different order or not performed depending on specific applications. It should be noted that method 1700 may not produce a complete semiconductor device 200. Accordingly, it is understood that additional processes can be provided before, during, and after method 1700, and that some other processes may only be briefly described herein. The discussion of elements in FIGS. 2A, 2B, and 18-22 with the same annotations applies to each other, unless mentioned otherwise.

Referring to FIG. 17, in operation 1705, first and second oxide layers are formed on a substrate. For example, as described with reference to FIG. 18, IL layer 212A (also referred to as “first oxide layer 212A”) and HK gate oxide layer 212B (also referred to as “second oxide layer 212B”) are formed on substrate 204. In some embodiments, the process of forming IL layer 212A and HK gate oxide layer 212B can be same as the process of forming IL layer 112A and HK gate oxide layer 112B, respectively, in operation 310, as described with reference to FIGS. 3-5.

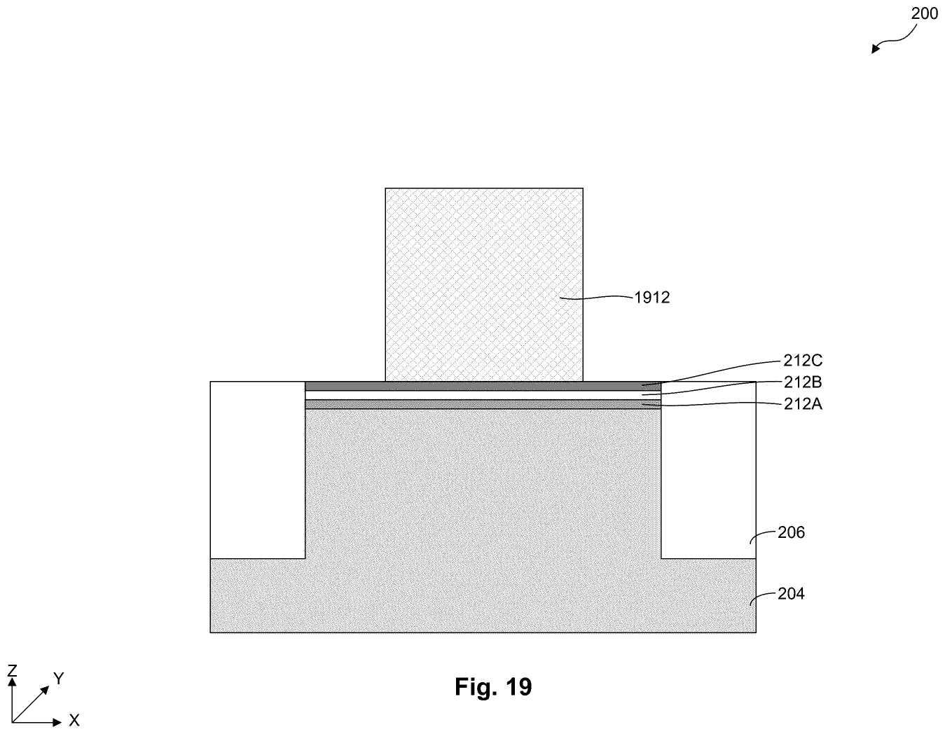

Referring to FIG. 17, in operation 1710, a first diffusion barrier layer is formed on the second oxide layer. For example, as described with reference to FIG. 18, first diffusion barrier layer 212C is formed on HK gate oxide layer 212B. In some embodiments, the process of forming first diffusion barrier layer 212C can be same as the process of forming first diffusion barrier layer 112C in operation 315, as described with reference to FIGS. 3-5. The formation of first diffusion barrier layer 212C can be followed by the formation of STI regions 206, as shown in FIG. 19.

Referring to FIG. 17, in operation 1715, a polysilicon structure is formed on the first diffusion barrier layer. For example, as shown in FIG. 19, polysilicon structure 1912 is formed directly on first diffusion barrier layer 212C.

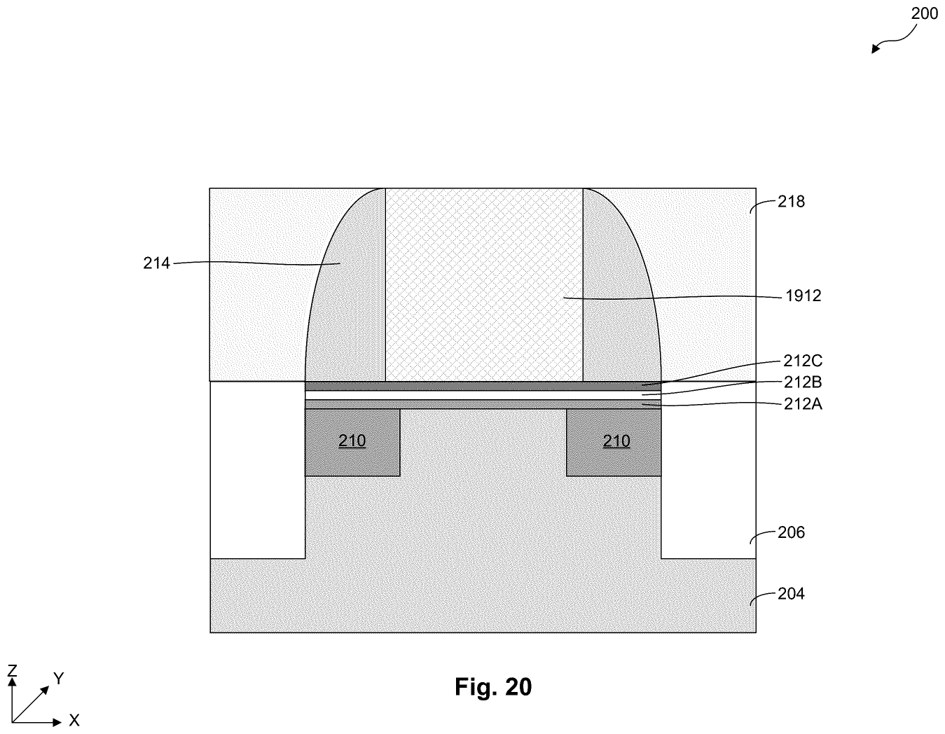

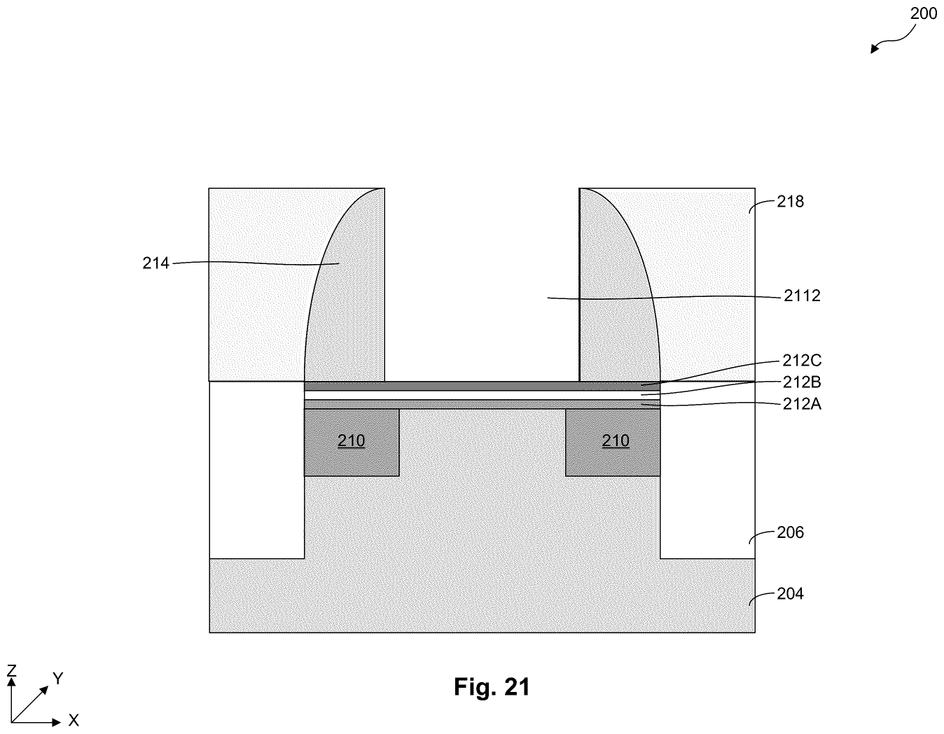

Referring to FIG. 17, in operation 1720, S/D regions are formed in the substrate. For example, as described with reference to FIG. 20, S/D regions 210 are formed in substrate 204. In some embodiments, the formation of S/D regions 110 can include forming doped regions in substrate 204 by performing doping processes in substrate 204 through first and second oxide layers 212A and 212B, and first diffusion barrier layer 212C.

Referring to FIG. 17, in operation 1725, gate spacers are formed along sidewalls of the polysilicon structure and on the first diffusion barrier layer. For example, as shown in FIG. 20, gate spacers 214 are formed along sidewalls of polysilicon structure 1912 and on first diffusion barrier layer 212C. The formation of gate spacers 214 can be followed by the formation of ILD layers 218, as shown in FIG. 20.

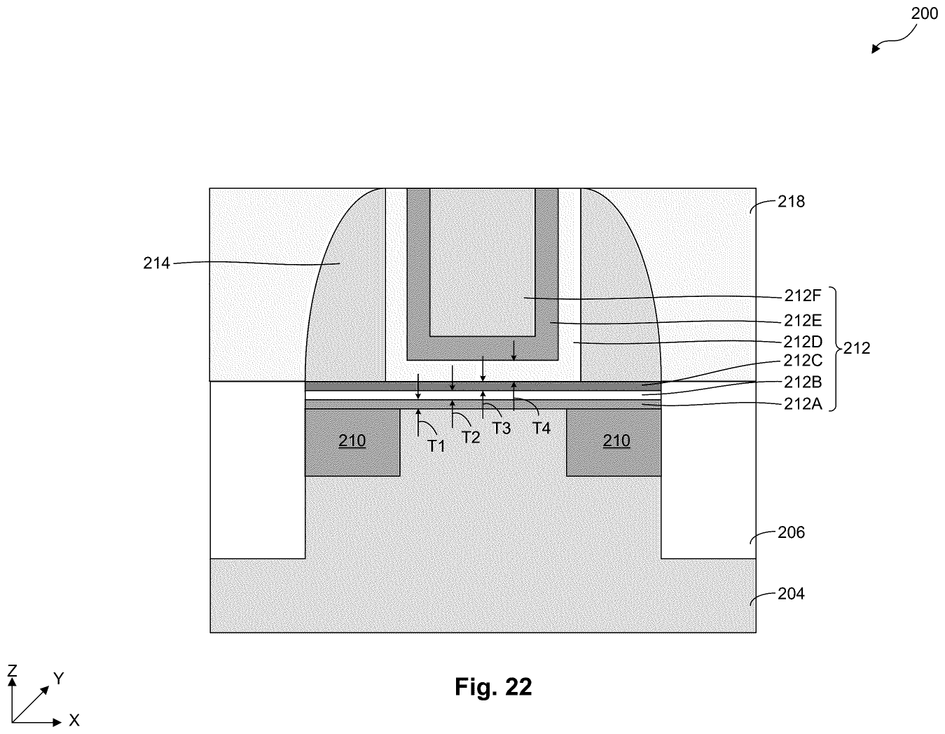

Referring to FIG. 17, in operation 1730, the polysilicon structure is replaced with a second diffusion barrier layer, a WFM layer, and a gate metal fill layer. For example, as described with reference to FIGS. 21 and 22, polysilicon structure 1912 is replaced with second diffusion barrier layer 212D, WFM layer 212E, and gate metal fill layer 212F. In some embodiments, the replacement of polysilicon structure 1912 with second diffusion barrier layer 212D, WFM layer 212E, and gate metal fill layer 212F can include sequential operations of (i) etching polysilicon structure 1912 to form gate opening 2112, as shown in FIG. 21, (ii) depositing second diffusion barrier layer 212D in gate opening 2112, (iii) depositing WFM layer 212E on second diffusion barrier layer 212D, (iv) depositing gate metal fill layer 212F on WFM layer 212E, and (v) performing a CMP process to substantially coplanarize top surfaces of second diffusion layer 212D, WFM layer 212E, and gate metal fill layer 212F with top surfaces of ILD layer 218, as shown in FIG. 22.

In some embodiments, semiconductor device 200 with the cross-sectional view of FIG. 2B can be formed using method 1700 as described above with reference to FIG. 17-22, except (i) operation 1705 can be followed by operation 1715, (ii) polysilicon structure 1912 can be formed directly on HK gate oxide layer 212B in operation 1715, instead of being formed directly on first diffusion barrier layer 212C in operation 1710, (iii) spacers 214 can be formed directly on HK gate oxide layer 212B in operation 1725, instead of being formed directly on first diffusion barrier layer 212C in operation 1725, and (iv) first diffusion barrier layer 212C can be formed in gate opening 2112 after the removal of polysilicon structure 1912 and prior to the formation of second diffusion barrier layer 212D in operation 1730, instead of being formed in operation 1710.

The present disclosure provides example gate structures (e.g., gate structures 112 and 212) with diffusion barrier layers (e.g., diffusion barrier layers 112C, 112D, 212C, and 212D) in FETs (e.g., FinFETs 100 and MOSFETs 200) and example methods (e.g., methods 300 and 1700) for forming such FETs to improve threshold voltage control in the FETs. In some embodiments, the example gate structure of a FET can include a high-k gate oxide layer (e.g., high-k gate oxide layer 112B or 212B), first and second diffusion barrier layers (e.g., first and second diffusion barrier layers 112C and 112D or 212C and 212D) disposed on the high-k gate oxide layer, and a gate metal fill layer (e.g., gate metal fill layer 112F or 212F) disposed on the first and second diffusion barrier layers. In some embodiments, the first and second diffusion barrier layers can be arranged to prevent or minimize the diffusion of metal atoms (e.g., Al atoms) from the gate metal fill layer to the high-k gate oxide layer. The presence of such diffused metal atoms in the high-k gate oxide layer can cause threshold voltage variations in the FET, and consequently, degrade the device performance. In some embodiments, the first diffusion barrier layer can be formed to have an amorphous structure and a structural density that can limit the concentration of metal atoms diffused from the gate metal fill layer into the first diffusion barrier layer to be at or below about 10 atomic %. Similarly, the second diffusion barrier layer can be formed to have an amorphous structure and a structural density that limit the concentration of metal atoms diffused from the gate metal fill layer into the second diffusion barrier layer to be between about 10 atomic % and about 50 atomic %. Within these concentration limitations, the diffusion of the metal atoms into the high-k gate oxide layer can be prevented or minimized.

In some embodiments, a semiconductor device includes a substrate, a fin structure disposed on the substrate, and a gate structure. The gate structure includes a high-k gate oxide layer disposed on the fin structure, a diffusion barrier layer disposed on the high-k gate oxide layer, and a metal layer disposed on the diffusion barrier layer. The semiconductor device further includes a gate spacer disposed on the diffusion barrier layer and a S/D region disposed on the fin structure. A sidewall of the S/D region is in contact with a sidewall of the high-k gate oxide layer.

In some embodiments, a semiconductor device includes a substrate and a gate structure. The gate structure includes an oxide layer disposed on the substrate, a diffusion barrier layer disposed on the oxide layer, and a metal layer disposed on the diffusion barrier layer. The semiconductor device further includes a gate spacer disposed on the diffusion barrier layer and a S/D region disposed in the substrate. A top surface of the S/D region is in contact with a bottom surface of oxide layer.

In some embodiments, a method includes forming first and second oxide layers on a substrate, forming a first diffusion barrier layer on the second oxide layer, forming a polysilicon structure on the first diffusion barrier layer, forming a gate spacer on the first diffusion barrier layer and on the polysilicon structure, and replacing the polysilicon structure with a second diffusion barrier layer and a metal layer.

The foregoing disclosure outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device, comprising:
a substrate;
a gate structure, comprising;
an oxide layer disposed on the substrate,
a first metal nitride layer disposed on the oxide layer,
a second metal nitride layer disposed on the first metal nitride layer, and
a metal layer disposed on the second metal nitride layer; and
a gate spacer disposed on the first metal nitride layer.

2. The semiconductor device of claim 1, wherein the first metal nitride layer comprises aluminum dopants.

3. The semiconductor device of claim 1, wherein the first metal nitride layer comprises sidewalls with a sloped profile.

4. The semiconductor device of claim 1, wherein the second metal nitride layer comprises a U-shaped cross-sectional profile.

5. The semiconductor device of claim 1, wherein materials of the first and second metal nitride layers are different from each other.

6. The semiconductor device of claim 1, wherein the gate spacer is disposed on a top surface of the first metal nitride layer.

7. The semiconductor device of claim 1, wherein the gate spacer is disposed on a top surface of the oxide layer and along a sidewall of the first metal nitride layer.

8. The semiconductor device of claim 1, wherein a horizontal portion of the gate spacer is disposed on the first metal nitride layer, and
wherein a vertical portion of the gate spacer is disposed on the second metal nitride layer.

9. The semiconductor device of claim 1, further comprising a source/drain (S/D) region disposed on the substrate, wherein a sidewall of the S/D region is in contact with a sidewall of the oxide layer.

10. The semiconductor device of claim 9, further comprising an etch stop layer disposed on the S/D region, wherein a sidewall of the etch stop layer is in contact with a sidewall of the first metal nitride layer.

11. A semiconductor device, comprising:
a substrate;
a gate structure, comprising;
a first oxide layer disposed on the substrate,
a second oxide layer disposed on the first oxide layer;
a first nitride layer disposed on the second oxide layer, and
a metal layer disposed on the first nitride layer;
a gate spacer disposed on the first nitride layer; and
a source/drain (S/D) region disposed in the substrate, wherein a sidewall of the S/D region is in contact with sidewalls of the first and second oxide layers.

12. The semiconductor device of claim 11, wherein the first nitride layer comprises aluminum dopants.

13. The semiconductor device of claim 11, further comprising an etch stop layer disposed on the S/D region, wherein a sidewall of the etch stop layer is in contact with a sidewall of the first nitride layer.

14. The semiconductor device of claim 11, wherein the gate spacer is disposed on a top surface of the first nitride layer.

15. The semiconductor device of claim 11, wherein the gate spacer is disposed on a top surface of the first oxide layer and along a sidewall of the first nitride layer.

16. The semiconductor device of claim 11, further comprising a second nitride layer disposed on the first nitride layer, wherein the second nitride layer comprises aluminum dopants.

17. A method, comprising:
performing an oxidation process on a fin structure on a substrate to form an oxide layer;
depositing a first nitride layer on the oxide layer;
forming a polysilicon structure on the first nitride layer;
forming a gate spacer on the first nitride layer and on the polysilicon structure; and
replacing the polysilicon structure with a second nitride layer and a metal layer.

18. The method of claim 17, wherein depositing the first nitride layer comprises depositing a metal nitride monolayer on the oxide layer.

19. The method of claim 17, wherein depositing the first nitride layer comprises depositing an amorphous metal nitride layer on the oxide layer.

20. The method of claim 17, further comprising doping a region in the substrate through the oxide layer and the first nitride layer to form a source/drain region.
